(19) United States
(12) Patent Application Publication
(10) Pub. No.: US 2025/0053842 A1
(43) Pub. Date: Feb. 13, 2025

(54) SYSTEMS AND METHODS FOR INCREASING ENERGY-SCALE BY MINIMIZING QUBIT INDUCTANCE

(71) Applicant: D-WAVE SYSTEMS INC., Burnaby (CA)

(72) Inventor: Emile M. Hoskinson, Vancouver (CA)

(21) Appl. No.: 18/718,588

(22) PCT Filed: Dec. 14, 2022
(86) PCT No.: PCT/US2022/081515

§ 371 Date: Jun. 11, 2024

Related U.S. Application Data
(60) Provisional application No. 63/265,388, filed on Dec. 14, 2021.

(51) Int. Cl. G06N 10/40; H03K 17/92

(52) U.S. Cl. CPC G06N 10/40; H03K 17/92

(57) ABSTRACT

In a superconducting quantum processor, inductance is a characteristic of superconducting flux qubits and used to achieve coupling between qubits. In general, higher qubit energy scale results in better quantum processor performance. Energy scale of qubits can be increased by reducing inductance. For each Ising spin problem, qubit energy scale can be increased by determining the unused inductance-tuner range for each qubit and the minimum homogenized inductance achievable across all qubits, then adjusting the inductance-tuner to achieve the minimum homogenized inductance. When the inductance of a qubit is changed, there is a shift in the CCJJ bias at which quantum annealing is performed for that qubit. The variation in CCJJ bias shift can be compensated by computing the shift in CCJJ bias due to the applied inductance and applying a compensating CCJJ bias via the CCJJ offset DAC.

### CROSS-REFERENCE TO RELATED APPLICATION

This patent application claims priority to U.S. Patent Application No. 63/265,388, filed on Dec. 14, 2021, the entire disclosure of which is hereby incorporated by reference herein for all purposes.

### FIELD

This disclosure generally relates to systems and methods for increasing energy scale in quantum computing systems by reducing or minimizing qubit inductance.

### BACKGROUND

### Energy in Inductive Coupling

The energy scale for specifying a problem Hamiltonian on a quantum processor is given by M_{AFM}Iₚ² where M_{AFM} is the maximum anti-ferromagnetic mutual inductance between two superconducting devices communicatively coupled by a coupling device such as two communicatively coupled qubits and Iₚ is the average persistent current of the two superconducting devices. It is desirable to increase this energy scale to improve the performance of the quantum processor. However, coupling devices have an upper-limit to the mutual inductance between two communicatively coupled superconducting devices which is set by the coupler inductance and the device-to-coupler mutual inductance. The maximum anti-ferromagnetic mutual inductance between two communicatively coupled superconducting devices is given by:

$${M}_{AFM} = {M}_{1} {M}_{2} {X}_{AFM}$$

where M₁ is the mutual inductance between the first superconducting device and the coupling device, M₂ is the mutual inductance between the second superconducting device and the coupling device, and X_{AFM} is the maximum susceptibility of the coupling device (i.e., how strongly the coupling device couples the two superconducting devices together). The susceptibility of a coupling device is set by a flux bias of the coupling device given by Φ_{co}. Increasing the critical current I_{c} of the coupler will increase X_{AFM} to an upper limit of 1/L_{co} where L_{co} denotes the inductance of the coupler. Therefore, by increasing the critical current of the coupling devices in a quantum processor by a large factor (e.g., more than 10 times the persistent current), X_{AFM} can be almost doubled. However, increasing the critical current of a coupling device increases the coupler's screening parameter or beta (a convenience parameter representing the behavior of a superconducting loop such as a qubit or coupling device that is used for modeling purposes). The beta (β) of a device is given by:

$$β = \frac{2 π {L}_{X} {I}_{C}}{{ϕ}_{0}}$$

where Φ₀ is the flux quantum, and L_{X} is the inductance of a device labeled X. For example, L_{CO} would be for a coupler and L_{QU} would be for a qubit. Increasing coupler beta increases the slope of the coupler susceptibility in the ferromagnetic region. Therefore, the coupler critical current cannot be increased by much without sacrificing the precision to which ferromagnetic/anti-ferromagnetic couplings can be specified.

### Tunable Inductance

Inductance is the tendency of an electrical conductor to oppose a change in the electric current flowing through it. A component that adds inductance to a circuit is referred to in the present application as an inductor. An ideal inductor has no resistance and therefore no power dissipation. An inductor may include a length, a coil, a spiral, or a helix of wire. Current flowing through an inductor can generate a magnetic field in which energy can be stored. The magnetic energy stored in an inductor can be proportional to the square of the current flowing through the inductor.

There is thus a general desire for systems and methods for increasing qubit energy scale in quantum processing systems.

The foregoing examples of the related art and limitations related thereto are intended to be illustrative and not exclusive. Other limitations of the related art will become apparent to those of skill in the art upon a reading of the specification and a study of the drawings.

### BRIEF SUMMARY

There exists a need to increasing qubit energy scale in quantum processing systems.

A method for increasing available qubit energy scale in a hybrid computing system is described. The hybrid computing system comprises a quantum processor and at least one digital processor. The quantum processor comprises a plurality of qubits and couplers, and each qubit has a respective qubit body comprising a loop of superconducting material interrupted by at least one compound-compound Josephson junction (CCJJ). The qubit body is communicatively coupled to an inductance tuner (L-tuner). The method is executed by the at least one digital processor and comprises: causing a respective L-tuner of at least a set of qubits to compensate for a coupler inductance loading: determining a remaining respective L-tuner range for each qubit in the set of qubits: computing a minimum homogenized inductance across all qubits in the set of qubits from the remaining respective L-tuner range; causing a respective L-tuner of each qubit in the set of qubits to apply an inductance ΔL to each qubit in the set of qubits to achieve the minimum homogenized inductance; computing a first shift in CCJJ bias Δ_{CCJJ} due to the applied inductance ΔL; and causing a respective CCJJ offset DAC of each qubit in the set of qubits to apply a respective second CCJJ bias shift −Δ_{CCJJ}*(M_{ccjj}−mean(M_{ccjj})) to each qubit in the set of qubits, wherein M_{ccjj} is a mutual inductance between a respective CCJJ analog bias line and a respective lobe of the CCJJ and mean(M_{ccjj}) is a calculated mean value of M_{ccjj} across all qubits. The method may further comprise applying a spin reversal transformation to increase a minimum sum of coupling strength/across all qubits in the set of qubits before causing a respective L-tuner of each qubit in the set of qubits to compensate for a coupler inductance loading.

The method may further comprise computing a model of a shift in a qubit CCJJ bias as a function of qubit inductance at a tunneling rate. Computing the model of the shift in the qubit CCJJ bias as a function of qubit inductance at a tunneling rate may include computing the model of the shift in the qubit CCJJ bias as a function of qubit inductance at 1 GHz. Computing a first shift in CCJJ bias Δ_{CYJ} due to the applied inductance ΔL may include computing a first shift in CCJJ bias Δ_{CCJJ} due to the applied inductance ΔL based on the computation of the model of the shift in the qubit CCJJ bias as a function of qubit inductance at a tunneling rate. Computing the minimum homogenized inductance across all qubits may include: comparing a remaining respective L-tuner range for each qubit in the set of qubits; selecting a smallest remaining L-tuner range; and subtracting the smallest remaining L-tuner range from an inductance of the qubit with the smallest remaining L-tuner range to be the minimum homogenized inductance. The method may further comprise compensating for a crosstalk between a CCJJ offset DAC and the respective qubit body for each qubit in the set of qubits. Compensating for a crosstalk between the CCJJ offset DAC and the respective qubit body for each qubit in the set of qubits may include measuring an offset from each respective CCJJ offset DAC and causing a respective qubit flux bias to compensate for the measured offset. Causing a respective L-tuner of at least a set of qubits to compensate for a coupler inductance loading may include causing a respective L-tuner of each qubit in the set of qubits to compensate for a coupler inductance loading wherein each qubit in the set of qubits is utilized for an Ising spin problem to be computed by the quantum processor. Causing a respective L-tuner of each qubit in the set of qubits to apply an inductance ΔL to each qubit in the set of qubits may include causing a respective L-tuner of each qubit in the set of qubits to apply an inductance ΔL=−M_{afm}[a+min(Σⱼ Jᵢⱼ)], wherein M_{afm} is the maximum antiferromagnetic coupling between two qubits, a is a constant, and ΣⱼJᵢⱼ is the sum of coupling strengths Jᵢⱼ between qubit i and coupled qubits j. Causing a respective L-tuner of each qubit in the set of qubits to apply an inductance ΔL to each qubit in the set of qubits may include causing a respective L-tuner of each qubit in the set of qubits to apply an inductance ΔL=−M_{afm}[a+min(ΣⱼJᵢⱼ)], where a depends on a minimum allowed sum of coupling strength J.

A hybrid computing system may comprise: a quantum processor, the quantum processor comprising a plurality of qubits and couplers, each qubit in the plurality of qubits comprising a respective qubit body, the qubit body comprising a loop of superconducting material interrupted by at least one compound-compound Josephson junction (CCJJ), the qubit body communicatively coupled to an inductance tuner (L-tuner), the CCJJ communicatively coupled to a respective CCJJ analog bias line and a respective CCJJ offset DAC: at least one digital processor; and at least one non-transitory computer-readable storage medium communicatively coupled to the at least one digital processor and that stores processor-executable instructions which, when executed, causes the at least one digital processor to: cause a respective L-tuner of at least a set of qubits to compensate for a coupler inductance loading; determine a remaining respective L-tuner range for each qubit in the set of qubits; compute a minimum homogenized inductance across all qubits in the set of qubits from the remaining respective L-tuner range; cause a respective L-tuner of each qubit in the set of qubits to apply an inductance ΔL to each qubit in the set of qubits to achieve the minimum homogenized inductance; compute a first shift in CCJJ bias Δ_{CCJJ} due to the applied inductance ΔL; and cause a respective CCJJ offset DAC of each qubit in the set of qubits to apply a respective second CCJJ bias shift −Δ_{CCJJ}*(M_{ccjj}−mean(M_{ccjj})) to each qubit in the set of qubits, wherein M_{ccjj} is a mutual inductance between a respective CCJJ analog bias line and a respective lobe of the CCJJ and mean(M_{ccjj}) is a calculated mean value of M_{ccjj} across all qubits. Each qubit body may be galvanically coupled to a respective L-tuner. The processor-executable instructions, when executed, may further cause the at least one digital processor to apply a spin reversal transformation to increase a minimum sum of coupling strength/across all qubits before causing a respective L-tuner of each qubits in the set of qubits to compensate for a coupler inductance loading. The processor-executable instructions, when executed, may cause the at least one digital processor to compute model of a shift in a qubit CCJJ bias as a function of qubit inductance at a tunneling rate. The processor-executable instructions, when executed, may cause the at least one digital processor to compute the model of the shift in the qubit CCJJ bias as a function of qubit inductance at 1 GHz. The processor-executable instructions, when executed, may cause the at least one digital processor to compute a first shift in CCJJ bias Δ_{CCJJ} due to the applied inductance ΔL based on the computation of the model of the shift in the qubit CCJJ bias as a function of qubit inductance at a tunneling rate. The processor-executable instructions, when executed, may cause the at least one digital processor to compute the minimum homogenized inductance across all qubits in the set of qubits by: comparing a remaining respective L-tuner range for each qubit in the set of qubits; selecting a smallest remaining L-tuner range; and subtracting the smallest remaining L-tuner range from an inductance of the qubit with the smallest remaining L-tuner range to be the minimum homogenized inductance. The processor-executable instructions, when executed, may further cause the at least one digital processor to compensate for a crosstalk between a CCJJ offset DAC and the respective qubit body for each qubit in the set of qubits. The processor-executable instructions, when executed, may cause the at least one digital processor to compensate for a crosstalk between a CCJJ offset DAC and the respective qubit body for each qubit in the set of qubits by measuring an offset from each respective CCJJ offset DAC and causing a respective qubit flux bias to compensate for the measured offset. Each qubit in the set of qubits may be utilized for an Ising spin problem to be computed by the quantum processor. The processor-executable instructions, when executed, may cause the at least one digital processor to cause a respective L-tuner of each qubit in the set of qubits to apply an inductance ΔL to each qubit in the set of qubits, wherein ΔL=−M_{afm}[a+min(ΣⱼJᵢⱼ)], M_{afm} is maximum antiferromagnetic coupling between two qubits, a is a constant, and ΣⱼJᵢⱼ is the sum of coupling strengths Jᵢⱼ between qubit i and coupled qubits j in the quantum processor. The processor-executable instructions, when executed, may cause the at least one digital processor to cause a respective L-tuner of each qubit in the set of qubits to apply an inductance ΔL to each qubit in the set of qubits, wherein ΔL=−M_{afm}[a+min(ΣⱼJᵢⱼ)], where a depends on a minimum allowed sum of coupling strength J.

### BRIEF DESCRIPTION OF THE SEVERAL VIEWS OF THE DRAWING(S)

In the drawings, identical reference numbers identify similar elements or acts. The sizes and relative positions of elements in the drawings are not necessarily drawn to scale. For example, the shapes of various elements and angles are not necessarily drawn to scale, and some of these elements may be arbitrarily enlarged and positioned to improve drawing legibility. Further, the particular shapes of the elements as drawn, are not necessarily intended to convey any information regarding the actual shape of the particular elements, and may have been solely selected for ease of recognition in the drawings.

FIG. 1 is a schematic diagram of an example hybrid computing system comprising a quantum processor and a digital processor

FIG. 2 is a schematic diagram of an example superconducting flux qubit comprising an inductance tuner.

FIG. 3 is a schematic diagram of another example superconducting flux qubit comprising an inductance tuner.

FIG. 4 is a flow chart of an example method for increasing energy-scale by reducing or minimizing qubit inductance.

### DETAILED DESCRIPTION

In the following description, certain specific details are set forth in order to provide a thorough understanding of various disclosed implementations. However, one skilled in the relevant art will recognize that implementations may be practiced without one or more of these specific details, or with other methods, components, materials, etc. In other instances, well-known structures associated with computer systems, server computers, and/or communications networks have not been shown or described in detail to avoid unnecessarily obscuring descriptions of the implementations.

Unless the context requires otherwise, throughout the specification and claims that follow, the word “comprising” is synonymous with “including,” and is inclusive or open-ended (i.e., does not exclude additional, unrecited elements or method acts).

Reference throughout this specification to “one implementation” or “an implementation” means that a particular feature, structure or characteristic described in connection with the implementation is included in at least one implementation. Thus, the appearances of the phrases “in one implementation” or “in an implementation” in various places throughout this specification are not necessarily all referring to the same implementation. Furthermore, the particular features, structures, or characteristics may be combined in any suitable manner in one or more implementations.

As used in this specification and the appended claims, the singular forms “a,” “an,” and “the” include plural referents unless the context clearly dictates otherwise. It should also be noted that the term “or” is generally employed in its sense including “and/or” unless the context clearly dictates otherwise.

The headings and Abstract of the Disclosure provided herein are for convenience only and do not interpret the scope or meaning of the implementations.

### Hybrid Quantum Computing System

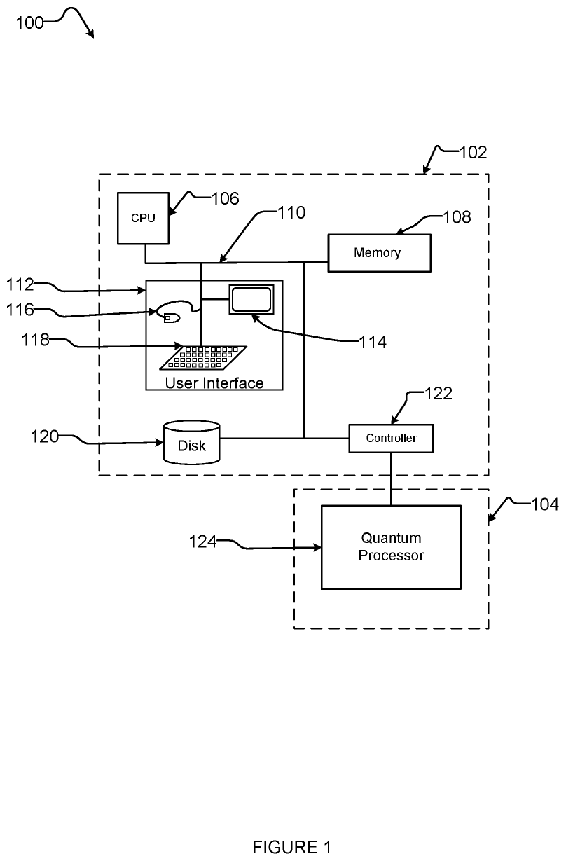

FIG. 1 illustrates a hybrid computing system 100 including a classical computer 102 coupled to a quantum computer 104. The example classical computer 102 includes a digital processor (CPU) 106 that may be used to perform classical digital processing tasks, and hence is denominated herein and in the claims as a classical processor.

Classical computer 102 may include at least one digital processor 106 (such as a central processor unit with one or more cores), at least one system memory 108, and at least one system bus 110 that couples various system components, including system memory 108 to digital processor 106. The digital processor may be any logic processing unit, such as one or more central processing units (“CPUs”), graphics processing units (“GPUs”), digital signal processors (“DSPs”), application-specific integrated circuits (“ASICs”), programmable gate arrays (“PGAs”), programmable logic controllers (PLCs), etc.

Classical computer 102 may include a user input/output subsystem 112. In some implementations, the user input/output subsystem includes one or more user input/output components such as a display 114, mouse 116, and/or keyboard 118.

System bus 110 can employ any known bus structures or architectures, including a memory bus with a memory controller, a peripheral bus, and a local bus. System memory 108 may include non-volatile memory, such as read-only memory (“ROM”), static random-access memory (“SRAM”), Flash NANO; and volatile memory such as random access memory (“RAM”) (not shown).

Classical computer 102 may also include other non-transitory computer or processor-readable storage media or non-volatile memory 120. Non-volatile memory 120 may take a variety of forms, including: a hard disk drive for reading from and writing to a hard disk, an optical disk drive for reading from and writing to removable optical disks, and/or a magnetic disk drive for reading from and writing to magnetic disks. The optical disk can be a CD-ROM or DVD, while the magnetic disk can be a magnetic floppy disk or diskette. Non-volatile memory 120 may communicate with the digital processor via system bus 110 and may include appropriate interfaces or controllers 122 coupled to system bus 110. Non-volatile memory 120 may serve as long-term storage for processor- or computer-readable instructions, data structures, or other data (sometimes called program modules) for classical computer 102.

Although classical computer 102 has been described as employing hard disks, optical disks and/or magnetic disks, those skilled in the relevant art will appreciate that other types of non-volatile computer-readable media may be employed, such magnetic cassettes, flash memory cards. Flash, ROMs, smart cards, etc. Those skilled in the relevant art will appreciate that some computer architectures employ volatile memory and non-volatile memory. For example, data in volatile memory can be cached to non-volatile memory, or a solid-state disk that employs integrated circuits to provide non-volatile memory.

Various processor- or computer-readable instructions, data structures, or other data can be stored in system memory 108. For example, system memory 108 may store instruction for communicating with remote clients and scheduling use of resources including resources on the classical computer 102 and quantum computer 104.

In some implementations system memory 108 may store processor- or computer-readable calculation instructions to perform pre-processing, co-processing, and post-processing to quantum computer 104. System memory 108 may store at set of quantum computer interface instructions to interact with quantum computer 104.

Quantum computer 104 may include one or more quantum processors such as quantum processor 124. Quantum computer 104 can be provided in an isolated environment, for example, in an isolated environment that shields the internal elements of the quantum computer from heat, magnetic field, and other external noise (not shown). Quantum processor 124 include programmable elements such as qubits, couplers and other devices. In some implementations, a quantum processor, such as quantum processor 124, may be designed to perform quantum annealing and/or adiabatic quantum computation. Examples of quantum processors for quantum annealing are described in U.S. Pat. No. 7,533,068.

Superconducting Qubits with L-Tuners

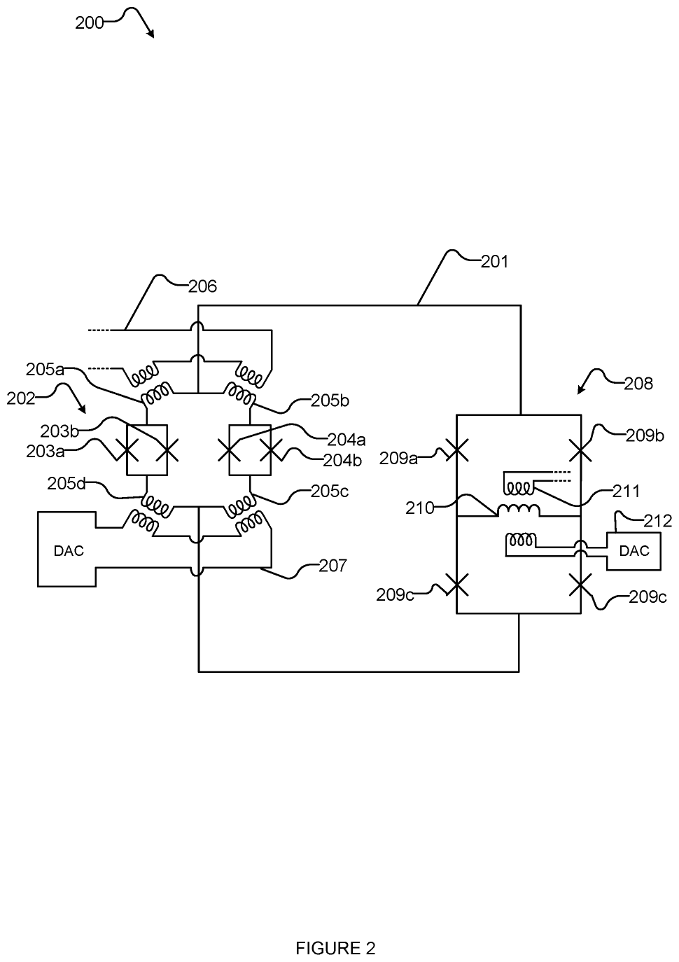

FIG. 2 is a schematic diagram of an example superconducting flux qubit 200 comprising an inductance tuner (also referred to herein as an L-tuner).

Example superconducting flux qubit 200 comprises a loop of superconducting material 201, interrupted by a compound-compound Josephson junction (CCJJ) 202. As used herein, a CCJJ refers to a compound Josephson junction (CJJ), wherein at least one of the parallel paths is itself a CJJ.

CCJJ 202 comprises four Josephson junctions 203a-203b and 204a-204b. CCJJ 202 further comprises four inductive interfaces 205a, 205b, 205c, 205d. Interfaces 205a and 205b are inductively coupled to shared analog line 206. Analog line 206 may be shared by multiple qubits (not shown in FIG. 2) in series in a quantum processor and is operable to apply a bias to CCJJ 202. Analog line 206 provides the same current flow to multiple devices simultaneously, although the bias received at each individual device is dependent on the mutual inductance between analog line 206 and the individual device. Analog line 206 provides to each device a time dependent waveform that is used, for example, for quantum annealing. Interfaces 205c and 205d are inductively coupled to CCJJ offset Digital to Analog Converter (DAC) 207. CCJJ offset DAC 207 is operable to apply a static bias offset to CCJJ 202. CCJJ offset DAC 207 is not shared with any other qubit or device in a quantum processor and provides a static bias to only one qubit (e.g., superconducting flux qubit 200). In a quantum processor with a plurality of qubits, each CCJJ offset DAC 207 can provide a different bias to each qubit.

Qubit 200 further comprises an L-tuner 208, galvanically coupled to loop of superconducting material 201. L-tuner 208 comprises four Josephson junctions 209a, 209b, 209c, 209d and inductance 210. Inductance 210 is communicatively coupled to shared analog line 211 and DAC 212. Analog line 211 is shared between multiple L-tuners in series (not shown in FIG. 2) and provides the same current flow to multiple devices simultaneously, although the bias received at each individual device is dependent on the mutual inductance between analog line 211 and the individual device. Analog line 211 provides to each device a time dependent waveform. DAC 212 is not shared with any other L-tuner or device in a quantum processor and provides a static bias to only one L-tuner (e.g., L-tuner 208). In some implementations, analog line 211 is not present and only DAC 212 is used to provide a static bias to L-tuner 208. A person skilled in the art will understand that L-tuner 208 is an example implementation of an inductance tuner and, in other implementations, an L-tuner as discussed herein may include different physical structures (e.g., Josephson junctions, inductances . . . ). Further examples of L-tuners are described in International Patent Publication No WO2010028183A2.

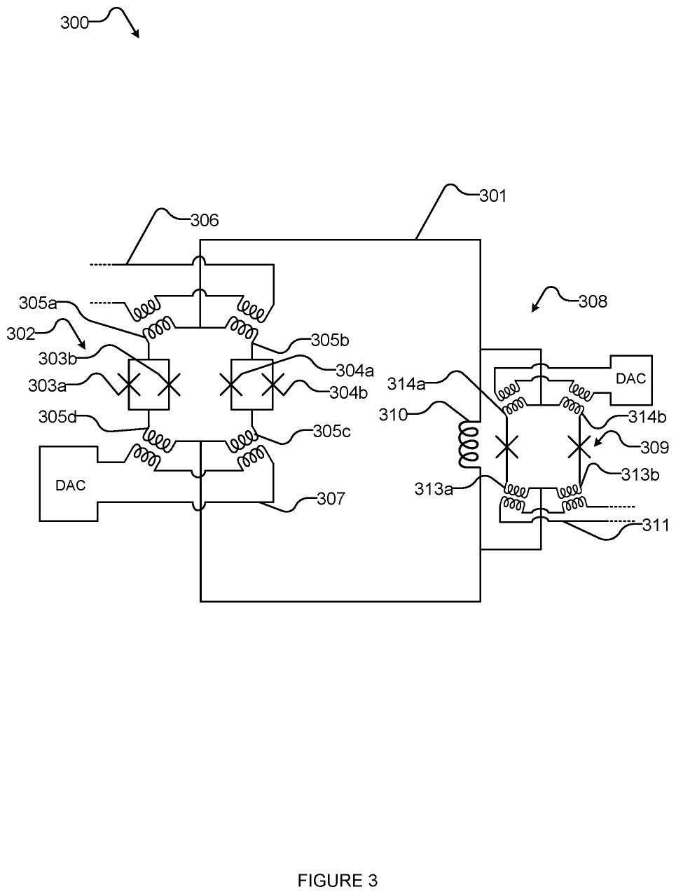

FIG. 3 is a schematic diagram of another example superconducting flux qubit 300 comprising an inductance tuner (or L-tuner).

Similar to superconducting flux qubit 200, example superconducting flux qubit 300 comprises a loop of superconducting material 301, interrupted by a compound-compound Josephson junction (CCJJ) 302.

CCJJ 302 comprises Josephson junctions 303a-303b and 304a-304b. CCJJ 302 further comprises inductive interfaces 305a. 305b. 305c, 305d. Interfaces 305a and 305b are inductively coupled to shared analog line 306. Analog line 306 may be shared by multiple qubits (not shown in FIG. 3) in series in a quantum processor and is operable to apply a bias to CCJJ 302. Analog line 306 provides the same current flow to multiple qubits simultaneously, although the bias received at each individual qubit is dependent on the mutual inductance between analog line 306 and the individual qubit. Analog line 306 provides to each qubit a time dependent waveform that is used, for example, for quantum annealing. Interfaces 305c and 305d are inductively coupled to CCJJ offset DAC 307. CCJJ offset DAC 307 is operable to apply a static bias offset to CCJJ 302. CCJJ offset DAC 307 is not shared with any other qubit or device in a quantum processor and provides a static bias to only one qubit (e.g., superconducting flux qubit 300). In a quantum processor with a plurality of qubits, each CCJJ offset DAC 307 can provide a different bias to each qubit.

Qubit 300 further comprises an L-tuner 308. L-tuner 308 provides the same capability to adjust inductance on a qubit as L-tuner 208 in an alternative implementation.

L-tuner 308 comprises compound Josephson junctions (CJJ) 309 and inductance 310. CJJ 309 is communicatively coupled to shared analog line 311 and DAC 312 via inductive interfaces 313a-313b and 314a-314b, respectively. Analog line 311 is shared between multiple L-tuners in series (not shown in FIG. 3) and provides the same current flow to multiple L-tuners simultaneously, although the bias received at each individual L-tuner is dependent on the mutual inductance between analog line 311 and the individual L-tuner. Analog line 311 provides to each L-tuner a time dependent waveform. DAC 312 is not shared with any other L-tuner or device in a quantum processor and provides a static bias to only one L-tuner (e.g., L-tuner 308). In some implementations, analog line 311 is not present and only DAC 312 used to provide a static bias to L-tuner 308. A person skilled in the art will understand that L-tuner 308 is an example implementation of an inductance tuner and, in other implementations, an L-tuner may be provided that includes different physical structures (e.g., Josephson junctions, inductances . . . ).

While the example implementations of FIG. 2 and FIG. 3 each show one L-tuner associated with a qubit, it will be understood that in other implementations, multiple L-tuners may be provided for a given qubit.

### Qubit Energy Scale

Qubit energy scale is a measure of the energy separation between the ground state and the first excited state of a qubit. In general, higher qubit energy scale results in better quantum processor performance, as a larger energy separation results in the processor being more likely to remain in a ground state throughout an annealing cycle or other quantum evolution. Higher qubit energy scale is therefore a desirable characteristic of a quantum annealing processor.

The goal of a quantum annealing processor is to find a ground state of a given Ising spin problem. Thermal fluctuations can cause the quantum processor system to be excited above the ground state, causing a computational errors and degeneration of system performance. For a given temperature, the probability of thermal excitation depends exponentially on energy scale. Therefore, even a modest increase in energy scale can yield large improvements in processor performance and it is thus desirable.

One approach to improve energy scale is to reduce or minimize qubit inductance. Qubit inductance is inversely proportional to qubit energy scale, so that the lower the qubit inductance, the higher the energy scale. However, some inductance is necessary for constructing a superconductive flux qubit and achieving coupling between qubits. In some implementations, the efficiency of qubit inductance may be improved through optimizing or improving the design and calibration of a quantum processor. For example, inductance can be improved during a design phase of a quantum processor by reducing or minimizing parasitic inductance that does not play a role in coupling. In design and in calibration, inductance can be homogenized across qubits.

The inductance of each qubit depends on the magnitude of the coupling strength of couplers that are coupled to the qubits.

Generally, each coupler modifies the inductance of the qubits it couples according to the relationship −MᵢⱼMᵢⱼχᵢⱼ, where Mᵢⱼ is the mutual inductance between qubit i and the coupling device that couples qubit i to qubit j, and χᵢⱼ is the susceptibility of the coupling device. When Mᵢⱼ is uniform across qubits and couplers, the formula above can be simplified to −M_{afm}*Jᵢⱼ, where M_{afm}=Mᵢⱼ Mᵢⱼχ_{afm} is the maximum antiferromagnetic coupling between two qubits, χ_{afm} is the maximum antiferromagnetic coupler susceptibility and Jᵢⱼ=χᵢⱼ/χ_{afm} is the normalized coupling strength. In an example implementation, M_{afm} may be 2 pH, such that a ferromagnetic coupling of Jᵢⱼ=−1 increases the qubit inductances by 2 pH, while an antiferromagnetic coupling of J=+1 decreases them by 2 pH.

The net change in inductance ΔL on qubit i is given by:

$$Δ {L}_{i} = - {M}_{afm} {\sum }_{j} {J}_{ij}$$

To compensate for the change in qubit inductance due to applied coupling required for a given problem, inductance-tuners (or L-tuners) are used. One or more L-tuners on each qubit is adjusted for each problem to compensate for coupler inductive loading and to bring the inductance of each qubit back to a baseline value. This baseline value may be chosen during a calibration phase of a quantum processor to be the minimum achievable for all allowed problems that will be submitted to the quantum processor.

L-tuners have a fixed inductance range over which the L-tuner can compensate. This means that for any problem, the sum of J on each qubit must be within a given range. For example, an allowed range may be

$$- a < {\sum }_{j} {J}_{ij} < b$$

Where the constants a and b depend on the L-tuner range and the number of couplers per qubit. The constant b may be, in some implementations, equal to the connectivity of a qubit in a given architecture of a quantum processor. The constant a is the minimum allowed sum of all Jᵢⱼ for any qubit i over all qubits j that are communicatively coupled to qubit i.

In an example implementation of a quantum processor with a qubit connectivity of 15 and −2<Jᵢⱼ<1, where the minimum allowed sum over the values of J is −18:

$$- 18 < {\sum }_{j} {J}_{ij} < 15$$

In the present description and the appended claims, an “allowed problem” is a problem where all the values for Jᵢⱼ and the sum of Jᵢⱼ for each qubit i meets an allowed range, such as the example allowed range provided above.

It is desirable to choose a baseline inductance that can be achieved for all qubits and all allowed problems to be submitted to the quantum processor. For any given problem, L-tuners are adjusted to compensate coupler inductive loading and maintain this baseline inductance. However, for many problems for which coupler inductive loading is not maximal, the full range of the L-tuners is not needed. Therefore, for these problems, there is L-tuner range that is not utilized and would be available to further reduce qubit inductance. It is desirable to make use of this non-utilized L-tuner range to reduce qubit inductance even further and thus increase qubit energy scale for some problems.

Boosting Energy Scale with Unused L-Tuner Range

For a given problem, if the full range of the L-tuners is not utilized, the remaining range may be used to reduce qubit inductance, which improves energy-scale. To keep the annealing schedules for all qubits homogenized, the inductance for all qubits should be decreased uniformly. For the example allowed range given above, the maximum drop in inductance ΔL is limited by the minimum ΣⱼJᵢⱼ.

$$Δ L = - {M}_{afm} ( a + min ( {\sum }_{j} {J}_{ij} ) )$$

Where the constant a depends on the range of coupling strength J for an allowed problem, as described above. For example, in some implementations, a=18.

It may be necessary to perform additional calibration to rebalance the qubits for a chosen min (ΣⱼJᵢⱼ) after further reducing the inductance.

It may be possible to increase the minimum sum of coupling strength J across all qubits, min (ΣⱼJᵢⱼ), for any given problem using spin reversal transformations. This may lead to a lower achievable qubit inductance compared to the qubit inductance of the original problem without spin reversal transformation. The term ‘spin reversal transformation’ is herein used to denote the principle that the flipping the sign of the ‘h’ (bias) applied to a qubit and the sign of the ‘J’ of all the couplers coupled to it leads to the same problem solution when the answer obtained for the flipped qubit is inverted. For example, a two-qubit problem with J=−1 can be transformed to a two-qubit problem with J=+1.

In some implementations, nonlinearity and flux offsets are introduced by L-tuners, and increase with L-tuner inductance. As such, reducing qubit inductance with unused L-tuner range may also improve L-tuner linearity and decrease L-tuner flux offsets.

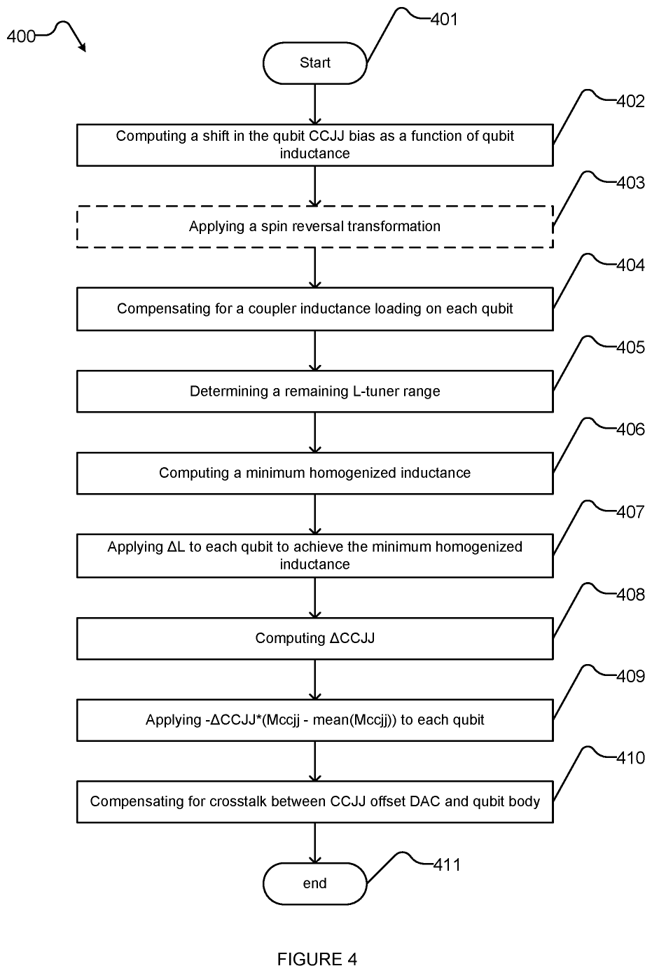

Quantum annealing is performed using a global bias line, for example analog line 206 or analog line 306 of FIG. 2 or FIG. 3, respectively, to vary the CCJJ bias of all qubits simultaneously from an initial value to a final value. When the inductance of a qubit is changed, due for example to applying a coupling strength, there is a shift in the CCJJ bias at which quantum annealing is performed for that qubit. This shift depends on the mutual inductance M_{ccjj} between the global CCJJ bias line and the qubit CCJJ loop. M_{ccjj} can vary between qubits, which can lead to a variation in the CCJJ bias shift, desynchronizing the qubits. The variation in CCJJ bias shift can be compensated using the CCJJ offset DAC, for example CCJJ offset DAC 207 or CCJJ offset DAC 307 of FIG. 2 or FIG. 3, respectively. A description of this compensation is included in the FIG. 4 flow chart.

FIG. 4 is a flow chart of an example method 400 for increasing energy-scale by reducing or minimizing qubit inductance. Method 400 may be executed by a digital processor in a hybrid computing system, for example hybrid computing system 100 of FIG. 1.

Method 400 comprises acts 401 to 411: however, a person skilled in the art will understand that the number of acts is an example, and, in some implementations, certain acts may be omitted, further acts may be added, and/or the order of the acts may be changed.

Method 400 starts at 401, for example in response to a call from another routine.

At 402, a digital processor, such as digital processor 106 of FIG. 1, computes a model of the shift in CCJJ bias in a qubit CCJJ as a function of qubit inductance. The method below will be discussed in terms of digital processor 106; however, it will be understood that the method may be performed by other implementations of digital processors. In some implementations, digital processor 106 computes a shift in CCJJ bias in a qubit CCJJ, for example CCJJ 202 or CCJJ 302 of qubits 200 or 300, respectively. Digital processor 106 may use a model of the qubit and calibrated qubit quantities to compute a CCJJ bias shift. Digital processor 106 may compute the CCJJ bias shift at a chosen tunneling rate that may be representative of a quantum computer, such as quantum computer 104, for example 1 GHz.

Act 402 may be performed once by digital processor 106 and the computed results reused in subsequent iterations of method 400. Acts 403 through 410 may be repeated for different Ising problems submitted to hybrid computing system 100.

At 403, optionally digital processor 106 applies a spin reversal transformation to increase the minimum sum of/across all qubits. This may lead to a lower achievable qubit inductance. Act 403 may be performed when an initial qubit inductance for a given problem is higher than a desired threshold.

At 404, digital processor 106 compensates for coupler inductive loading by adjusting the L-tuner of each qubit. In some implementations, where only a portion of the qubits in quantum processor 124 are utilized, for example to solve a computational problem, digital processor 106 adjust the L-tuner on the utilized qubits only.

At 405, digital processor 106 determines the remaining L-tuner range on each qubit. In some implementations, where only a portion of the qubits in quantum processor 124 are utilized, digital processor 106 only checks the remaining L-tuner range of the utilized qubits.

At 406, digital processor 106 computes the minimum homogenized inductance achievable across all qubits (or, in some implementations, across the utilized qubits). The minimum homogenized inductance can be computed by comparing all the remaining L-tuner ranges determined at 405 and selecting the inductance of the qubit with the smallest remaining L-tuner range and subtracting from it the smallest remaining L-tuner range. In some implementations, a minimum homogenized inductance may be selected to be larger than the inductance of the qubit with the smallest remaining L-tuner range determined at 405 and then subtracting from it the smallest remaining L-tuner range.

At 407, digital processor 106 applies an inductance ΔL to each qubit to achieve the minimum homogenized inductance. After act 407, the inductance of each qubit is the baseline inductance minus ΔL, where ΔL is maximized for each computational problem submitted to quantum computer 104. In some implementations, where only a portion of the qubits in quantum processor 124 are utilized, for example to solve a computational problem, digital processor 106 applies an inductance ΔL only to each utilized qubit.

At 408, digital processor 106 computes the shift in CCJJ bias Δ_{CCJJ} due to the applied inductance ΔL. The model of the shift in CCJJ bias in a qubit CCJJ as a function of qubit inductance computed at act 402 may be utilized to compute Δ_{CCJJ}.

At 409, digital processor 106 applies a CCJJ bias shift to each qubit (or to each utilized qubit) equal to −Δ_{CCJJ}*(M_{ccjj}−mean(M_{ccjj})) using the respective CCJJ offset DAC associated with each qubit, for example CCJJ offset DAC 207 or CCJJ offset DAC 307 of FIGS. 2 and 3, respectively. M_{ccjj} is the mutual inductance between a respective CCJJ analog bias line and the respective lobe of the CCJJ and mean(M_{ccjj}) is a calculated mean value of M_{ccjj} across all qubits. This will ensure or at least improve the qubits (or the utilized qubits) remaining synchronized at the tunneling rate at act 402.

At 410, digital processor 106 compensates for crosstalk between each qubit offset DAC and the qubit body. In some implementations, digital processor 106 measures the offset from each respective CCJJ offset DAC and compensates for the measured offset via the respective qubit flux bias.

At 411, method 400 terminates, until it is, for example, invoked again.

The above described method(s), process(es), or technique(s) could be implemented by a series of processor readable instructions stored on one or more nontransitory processor-readable media. Some examples of the above described method(s), process(es), or technique(s) method are performed in part by a specialized device such as an adiabatic quantum computer or a quantum annealer or a system to program or otherwise control operation of an adiabatic quantum computer or a quantum annealer, for instance a computer that includes at least one digital processor. The above described method(s), process(es), or technique(s) may include various acts, though those of skill in the art will appreciate that in alternative examples certain acts may be omitted and/or additional acts may be added. Those of skill in the art will appreciate that the illustrated order of the acts is shown for example purposes only and may change in alternative examples. Some of the example acts or operations of the above described method(s), process(es), or technique(s) are performed iteratively. Some acts of the above described method(s), process(es), or technique(s) can be performed during each iteration, after a plurality of iterations, or at the end of all the iterations.

The above description of illustrated implementations, including what is described in the Abstract, is not intended to be exhaustive or to limit the implementations to the precise forms disclosed. Although specific implementations of and examples are described herein for illustrative purposes, various equivalent modifications can be made without departing from the spirit and scope of the disclosure, as will be recognized by those skilled in the relevant art. The teachings provided herein of the various implementations can be applied to other methods of quantum computation, not necessarily the example methods for quantum computation generally described above.

The various implementations described above can be combined to provide further implementations. All of the commonly assigned US patent application publications, US patent applications, foreign patents, and foreign patent applications referred to in this specification and/or listed in the Application Data Sheet are incorporated herein by reference, in their entirety, including but not limited to: U.S. Pat. No. 7,533,068, and International Patent Publication No WO2010028183A2.

These and other changes can be made to the implementations in light of the above-detailed description. In general, in the following claims, the terms used should not be construed to limit the claims to the specific implementations disclosed in the specification and the claims, but should be construed to include all possible implementations along with the full scope of equivalents to which such claims are entitled. Accordingly, the claims are not limited by the disclosure.

1. A method for increasing available qubit energy scale in a hybrid computing system, the hybrid computing system comprising a quantum processor and at least one digital processor, the quantum processor comprising a plurality of qubits and couplers, each qubit having a respective qubit body comprising a loop of superconducting material interrupted by at least one compound-compound Josephson junction (CCJJ), the qubit body communicatively coupled to an inductance tuner (L-tuner), the method executed by the at least one digital processor and comprising:
causing a respective L-tuner of at least a set of qubits to compensate for a coupler inductance loading;
determining a remaining respective L-tuner range for each qubit in the set of qubits;
computing a minimum homogenized inductance across all qubits in the set of qubits from the remaining respective L-tuner range;
causing a respective L-tuner of each qubit in the set of qubits to apply an inductance ΔL to each qubit in the set of qubits to achieve the minimum homogenized inductance;
computing a first shift in CCJJ bias Δ_{CCJJ} due to the applied inductance ΔL; and
causing a respective CCJJ offset DAC of each qubit in the set of qubits to apply a respective second CCJJ bias shift −Δ_{CCJJ}*(M_{ccjj}−mean(M_{ccjj})) to each qubit in the set of qubits, wherein M_{ccjj} is a mutual inductance between a respective CCJJ analog bias line and a respective lobe of the CCJJ and mean(M_{ccjj}) is a calculated mean value of M_{ccjj} across all qubits.

2. The method of claim 1, further comprising applying a spin reversal transformation to increase a minimum sum of coupling strength/across all qubits in the set of qubits before causing a respective L-tuner of each qubit in the set of qubits to compensate for a coupler inductance loading.

3. The method of claim 1, further comprising computing a model of a shift in a qubit CCJJ bias as a function of qubit inductance at a tunneling rate.

4. The method of claim 3, wherein computing the model of the shift in the qubit CCJJ bias as a function of qubit inductance at a tunneling rate includes computing the model of the shift in the qubit CCJJ bias as a function of qubit inductance at 1 GHz.

5. The method of claim 3, wherein computing a first shift in CCJJ bias Δ_{CJJ} due to the applied inductance ΔL includes computing a first shift in CCJJ bias Δ_{CCJJ} due to the applied inductance ΔL based on the computation of the model of the shift in the qubit CCJJ bias as a function of qubit inductance at a tunneling rate.

6. The method of claim 1, wherein computing the minimum homogenized inductance across all qubits includes:
comparing a remaining respective L-tuner range for each qubit in the set of qubits;
selecting a smallest remaining L-tuner range; and
subtracting the smallest remaining L-tuner range from an inductance of the qubit with the smallest remaining L-tuner range to be the minimum homogenized inductance.

7. The method of claim 1, further comprising compensating for a crosstalk between a CCJJ offset DAC and the respective qubit body for each qubit in the set of qubits.

8. The method of claim 7, wherein compensating for a crosstalk between the CCJJ offset DAC and the respective qubit body for each qubit in the set of qubits includes measuring an offset from each respective CCJJ offset DAC and causing a respective qubit flux bias to compensate for the measured offset.

9. The method of claim 1, wherein causing a respective L-tuner of at least a set of qubits to compensate for a coupler inductance loading includes causing a respective L-tuner of each qubit in the set of qubits to compensate for a coupler inductance loading wherein each qubit in the set of qubits is utilized for an Ising spin problem to be computed by the quantum processor.

10. The method of claim 1, wherein causing a respective L-tuner of each qubit in the set of qubits to apply an inductance ΔL to each qubit in the set of qubits includes causing a respective L-tuner of each qubit in the set of qubits to apply an inductance ΔL=−M_{afm} [a+min(ΣⱼJᵢⱼ)], wherein M_{afm} is the maximum antiferromagnetic coupling between two qubits, a is a constant, and ΣⱼJᵢⱼ is the sum of coupling strengths Jᵢⱼ between qubit i and coupled qubits j.

11. The method of claim 10 wherein causing a respective L-tuner of each qubit in the set of qubits to apply an inductance ΔL to each qubit in the set of qubits includes causing a respective L-tuner of each qubit in the set of qubits to apply an inductance ΔL=−M_{afm} [a+min(ΣⱼJᵢⱼ)], where a depends on a minimum allowed sum of coupling strength J.

12. A hybrid computing system comprising:
a quantum processor, the quantum processor comprising a plurality of qubits and couplers, each qubit in the plurality of qubits comprising a respective qubit body, the qubit body comprising a loop of superconducting material interrupted by at least one compound-compound Josephson junction (CCJJ), the qubit body communicatively coupled to an inductance tuner (L-tuner), the CCJJ communicatively coupled to a respective CCJJ analog bias line and a respective CCJJ offset DAC;
at least one digital processor; and
at least one non-transitory computer-readable storage medium communicatively coupled to the at least one digital processor and that stores processor-executable instructions which, when executed, causes the at least one digital processor to:
cause a respective L-tuner of at least a set of qubits to compensate for a coupler inductance loading;
determine a remaining respective L-tuner range for each qubit in the set of qubits;
compute a minimum homogenized inductance across all qubits in the set of qubits from the remaining respective L-tuner range;
cause a respective L-tuner of each qubit in the set of qubits to apply an inductance ΔL to each qubit in the set of qubits to achieve the minimum homogenized inductance;
compute a first shift in CCJJ bias Δ_{CCJJ} due to the applied inductance ΔL; and
cause a respective CCJJ offset DAC of each qubit in the set of qubits to apply a respective second CCJJ bias shift −Δ_{CCJJ}*(M_{ccjj}−mean(M_{ccjj})) to each qubit in the set of qubits, wherein M_{ccjj} is a mutual inductance between a respective CCJJ analog bias line and a respective lobe of the CCJJ and mean(M_{ccjj}) is a calculated mean value of M_{ccjj} across all qubits.

13. The hybrid computing system of claim 12, wherein each qubit body is galvanically coupled to a respective L-tuner.

14. The hybrid computing system of claim 12, wherein the processor-executable instructions, when executed, further causes the at least one digital processor to apply a spin reversal transformation to increase a minimum sum of coupling strength/across all qubits before causing a respective L-tuner of each qubits in the set of qubits to compensate for a coupler inductance loading.

15. The hybrid computing system of claim 12, wherein the processor-executable instructions, when executed, causes the at least one digital processor to compute model of a shift in a qubit CCJJ bias as a function of qubit inductance at a tunneling rate.

16. The hybrid computing system of claim 15, wherein the processor-executable instructions, when executed, causes the at least one digital processor to compute the model of the shift in the qubit CCJJ bias as a function of qubit inductance at 1 GHz.

17. The hybrid computing system of claim 15, wherein the processor-executable instructions, when executed, causes the at least one digital processor to compute a first shift in CCJJ bias Δ_{CCJJ} due to the applied inductance ΔL based on the computation of the model of the shift in the qubit CCJJ bias as a function of qubit inductance at a tunneling rate.

18. The hybrid computing system of claim 12, wherein the processor-executable instructions, when executed, causes the at least one digital processor to compute the minimum homogenized inductance across all qubits in the set of qubits by:
comparing a remaining respective L-tuner range for each qubit in the set of qubits;
selecting a smallest remaining L-tuner range; and
subtracting the smallest remaining L-tuner range from an inductance of the qubit with the smallest remaining L-tuner range to be the minimum homogenized inductance.

19. The hybrid computing system of claim 12, wherein the processor-executable instructions, when executed, further causes the at least one digital processor to compensate for a crosstalk between a CCJJ offset DAC and the respective qubit body for each qubit in the set of qubits.

20. The hybrid computing system of claim 19, wherein the processor-executable instructions, when executed, causes the at least one digital processor to compensate for a crosstalk between a CCJJ offset DAC and the respective qubit body for each qubit in the set of qubits by measuring an offset from each respective CCJJ offset DAC and causing a respective qubit flux bias to compensate for the measured offset.

21. The hybrid computing system of claim 12, wherein each qubit in the set of qubits is utilized for an Ising spin problem to be computed by the quantum processor.

22. The hybrid computing system of claim 12, wherein the processor-executable instructions, when executed, causes the at least one digital processor to cause a respective L-tuner of each qubit in the set of qubits to apply an inductance ΔL to each qubit in the set of qubits, wherein ΔL=−M_{afm}[a+min(ΣⱼJᵢⱼ)], M_{afm} is maximum antiferromagnetic coupling between two qubits, a is a constant, and ΣⱼJᵢⱼ is the sum of coupling strengths Jᵢⱼ between qubit i and coupled qubits j in the quantum processor.

23. The hybrid computing system of claim 22, wherein the processor-executable instructions, when executed, causes the at least one digital processor to cause a respective L-tuner of each qubit in the set of qubits to apply an inductance ΔL to each qubit in the set of qubits, wherein ΔL=−M_{afm}[a+min(ΣⱼJᵢⱼ)], where a depends on a minimum allowed sum of coupling strength J.
